(19) United States
(12) Patent Application Publication
(10) Pub. No.: US 2005/0032300 A1
(43) Pub. Date: Feb. 10, 2005

(54) Methods of manufacturing metal-insulator-metal capacitors of high capacitance in semiconductor devices

(76) Inventor: Ki-Min Lee, Seoul (KR)

Correspondence Address: HANLEY, FLIGHT & ZIMMERMAN, LLC, 20 N. WACKER DRIVE, SUITE 4220, CHICAGO, IL, 60606, US

(21) Appl. No.: 10/750,489

(22) Filed: Dec. 31, 2003

(30) Foreign Application Priority Data
Aug. 7, 2003 (KR) 10-2003-0054587

(51) Int. Cl. H01L 21/8242

(52) U.S. Cl. 438/239

(57) ABSTRACT

In accordance with an example process for fabricating an MIM capacitor of high capacitance in a semiconductor device, an interlayer dielectric film is deposited on a metal line and etched to form an MIM capacitor forming region. The lower electrode, the insulator and the upper electrode are sequentially deposited on the interlayer dielectric film, and then etched to from an MIM capacitor.

### TECHNICAL FIELD

The present disclosure relates to semiconductors and, more particularly, to methods of manufacturing a metal-insulator-metal (“MIM”) capacitors of high capacitance in semiconductor devices.

### BACKGROUND

Referring to FIG. 1, generally, a conventional structure of an MIM capacitor includes an ARC (Antireflective Coated) TiN layer 20 deposited on a lower electrode (metal line) 10. An insulator layer 30 is deposited on the ARC TiN layer 20 and an upper electrode 40 is deposited on the insulator layer 30, sequentially.

In etching the insulator layer 30, however, the lower electrode (metal line) 10 is simultaneously etched, so that metallic polymers are sputtered on the surface of the lower electrode 10 and deposited on sidewalls of the insulator layer 30, thereby causing a short phenomenon. In addition, the upper electrode 40 and the lower electrode 10 are formed in a planar configuration. Accordingly, to form an MIM capacitor of high capacitance, a plan area of the electrodes should be increased.

### BRIEF DESCRIPTION OF THE DRAWINGS

FIG. 1 illustrates a cross sectional view of a conventional structure of an MIM capacitor in a semiconductor device.

FIGS. 2A to 2F depict cross sectional views sequentially showing an example disclosed process of fabricating an MIM capacitor.

FIGS. 3A to 3D offer cross sectional views sequentially showing a second example disclosed process of fabricating an MIM capacitor.

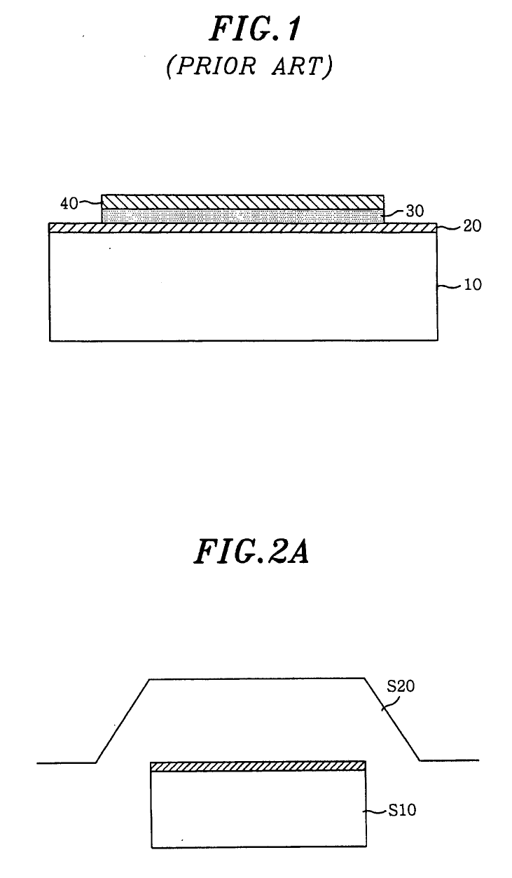

### DETAILED DESCRIPTION

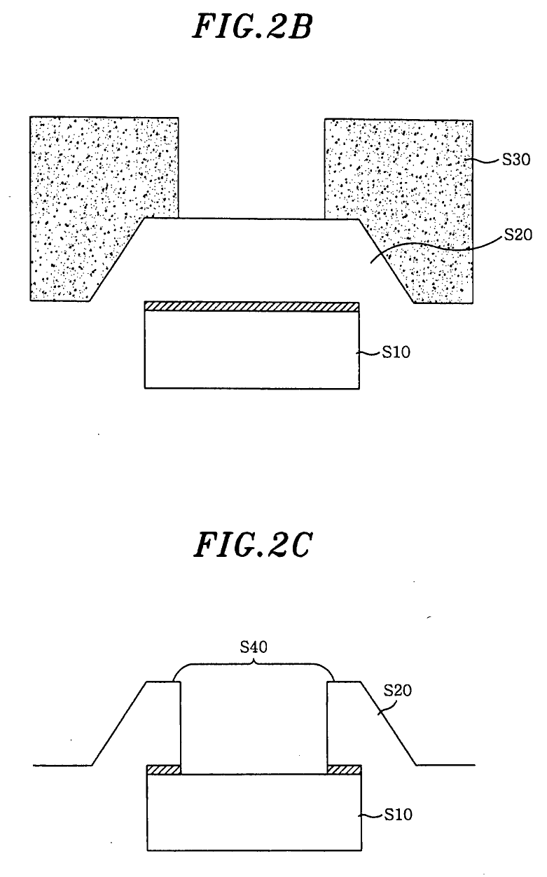

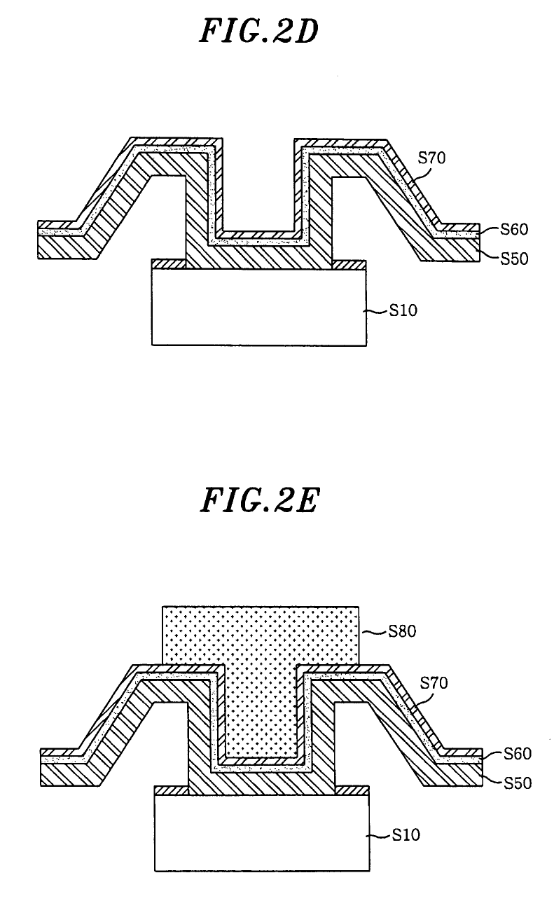

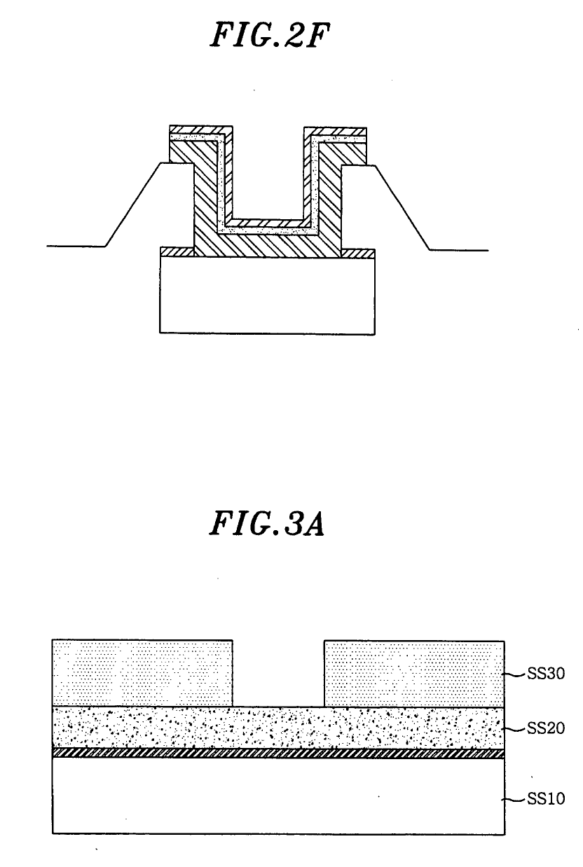

FIGS. 2A to 2F depict cross sectional views sequentially showing an example disclosed process of fabricating an MIM capacitor. As shown in FIG. 2A, an interlayer dielectric film S20, which may be made of USG (Undoped Silicate Glass) or TEOS (Tetraethoxysilane) and into which an MIM capacitor is to be formed, is deposited on a metal line S1. By controlling the thickness of the interlayer dielectric film S20, an MIM capacitor of desired capacitance may be fabricated.

Subsequently, referring to FIG. 2B, a photoresist pattern S30 is formed on the interlayer dielectric film S20, and as shown in FIG. 2C, the interlayer dielectric film S20 is etched to form an MIM capacitor forming region S40. The photoresist pattern S30 is then removed.

As shown in FIG. 2D, a lower electrode layer S50, an insulator layer S60 and an upper electrode layer S70 are sequentially deposited on the interlayer dielectric film S60 having the MIM capacitor forming region S40.

At this time, the lower electrode layer S50 may be made of Ti, W, TiN or the like; the insulator layer S60 is made of TaO₂, Al₂O₃, SiN or the like; the upper electrode layer S70 is made of Ru, Pt, TiN or the like.

Thereafter, a photoresist pattern S80 is formed on the upper electrode layer S70 as shown in FIG. 2E and an MIM capacitor as shown in FIG. 2F is formed by etching the lower electrode layer S50, the insulator layer S60 and the upper electrode layer S70 using the photoresist pattern S80 as a mask.

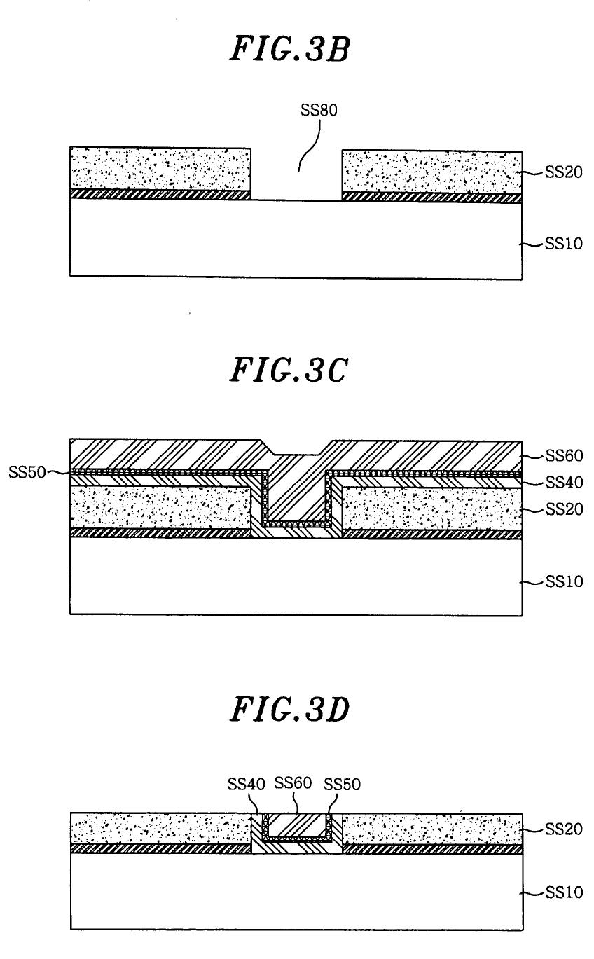

FIGS. 3A to 3D offer cross sectional views sequentially showing a second example disclosed process of fabricating an MIM capacitor. As shown in FIG. 3A, an interlayer dielectric film SS20 into which an MIM capacitor is to be formed is deposited on a metal line SS10. By controlling the thickness of the interlayer dielectric film SS20, an MIM capacitor of desired capacitance may be obtained. The interlayer dielectric film SS20 is then planarized by a CMP processor an etch-back process, and a photoresist pattern SS30 is formed thereon. Subsequently, as shown in FIG. 3B, the interlayer dielectric film SS20 is etched by using the photoresist pattern SS30 as a mask to form an MIM capacitor forming region SS80.

As shown in FIG. 3C, a lower electrode layer SS40, an insulator layer SS50 and an upper electrode layer SS60 are sequentially deposited on the interlayer dielectric film SS50 having the MIM capacitor forming region SS80.

According to one example, the lower electrode layer SS40 may be made of Ti, W, TiN or the like; the insulator layer SS50 may be made of TaO₂, Al₂O₃, SiN or the like; the upper electrode layer SS60 may be made of Ru, Pt, TiN or the like.

Finally, as shown in FIG. 3D, the lower electrode SS40, the insulator layer SS50 and the upper electrode SS60 are planarized to expose the interlayer dielectric film SS30 by a CMP process or an etch-back process.

According to the disclosed example processes, the MIM capacitor has an increased capacitance in proportion to the thickness of the interlayer dielectric film without increasing a plan area of the electrodes, thereby facilitating a high integration of the semiconductor device. Further, a short phenomenon, which may be caused by metallic polymers in a conventional process, is prevented.

According to a first example, a method for fabricating an MIM capacitor of high capacitance in a semiconductor device includes depositing an interlayer dielectric film on a metal line; etching the interlayer dielectric film to form an MIM capacitor forming region; sequentially depositing a lower electrode, an insulator layer and an upper electrode on the interlayer dielectric film; and etching the lower electrode, the insulator layer and the upper electrode to form an MIM capacitor.

According to a second disclosed example, a method of fabricating an MIM capacitor of high capacitance in a semiconductor device includes depositing an interlayer dielectric film on a metal line; planarizing the interlayer dielectric film; etching the interlayer dielectric film to form an MIM capacitor forming region; sequentially depositing a lower electrode, an insulator layer and an upper electrode on the interlayer dielectric film; and planarizing the lower electrode, the insulator layer and the upper electrode to form an MIM capacitor.

Although certain example methods are disclosed herein, the scope of coverage of this patent is not limited thereto. On the contrary, this patent covers every apparatus, method and article of manufacture fairly falling within the scope of the appended claims either literally or under the doctrine of equivalents.

1. A method of fabricating an MIM capacitor of high capacitance in a semiconductor device, the method comprising:
depositing an interlayer dielectric film on a metal line;
etching the interlayer dielectric film to form an MIM capacitor forming region;
sequentially depositing a lower electrode layer, an insulator layer and an upper electrode layer on the interlayer dielectric film; and
etching the lower electrode layer, the insulator layer and the upper electrode layer to form an MIM capacitor.

2. A method as defined by claim 1, wherein a capacitance of the MIM capacitor is determined by controlling a thickness of the interlayer dielectric film.

3. A method as defined by claim 1, wherein the interlayer dielectric film is made of USG or TEOS.

4. A method as defined by claim 1, wherein the lower electrode layer is made of Ti, W or TiN.

5. A method as defined by claim 1, wherein the insulator layer is made of TaO₂, Al₂O₃ or SiN.

6. A method as defined by claim 1, wherein the upper electrode layer is made of Ru, Pt or TiN.

7. A method of fabricating an MIM capacitor of high capacitance in a semiconductor device, the method comprising:
depositing an interlayer dielectric film on a metal line;
planarizing the interlayer dielectric film;
etching the interlayer dielectric film to form an MIM capacitor forming region;
sequentially depositing a lower electrode layer, an insulator layer and an upper electrode layer on the interlayer dielectric film; and
planarizing the lower electrode layer, the insulator layer and the upper electrode layer to form an MIM capacitor.

8. A method as defined by claim 7, wherein a capacitance of the MIM capacitor is determined by controlling a thickness of the interlayer dielectric film.

9. A method as defined by claim 7, wherein the interlayer dielectric film is planarized by a chemical mechanical polishing (CMP) process.

10. A method as defined by claim 7, wherein the interlayer dielectric film is planarized by an etch-back process.

11. A method as defined by claim 7, wherein the lower electrode layer is made of any one of Ti, W or TiN.

12. A method as defined by claim 7, wherein the insulator layer is made of any one of TaO₂, Al₂O₃ or SiN.

13. A method as defined by claim 7, wherein the upper electrode layer is made of any one of Ru, Pt or TiN.

14. A method as defined by claim 7, wherein the lower electrode layer, the insulator layer and the upper electrode layer are planarized by a chemical mechanical polishing (CMP) process.

15. A method as defined by claim 7, wherein the lower electrode layer, the insulator layer and the upper electrode layer are planarized by an etch-back process.
